(19) United States
(12) Patent Application Publication
(10) Pub. No.: US 2014/0354321 A1
(43) Pub. Date: Dec. 4, 2014

(54) AUTOMATED TEST MANAGEMENT SYSTEM FOR ELECTRONIC CONTROL MODULE

(71) Applicant: Caterpillar Inc., Peoria, IL (US)

(72) Inventors: Rajeev V. Kumar, Peoria, IL (US); Amanda J. Wilke, Peoria, IL (US); Adam R. Long, Hoffman Estates, IL (US)

(73) Assignee: Caterpillar Inc., Peoria, IL (US)

(21) Appl. No.: 14/459,413

(22) Filed: Aug. 14, 2014

(51) Int. Cl. G01R 31/28; G01R 1/04

(52) U.S. Cl. CPC G01R 31/2834; G01R 1/0408
USPC 324/756.02

(57) ABSTRACT

An automatable management system for testing one or more electronic control modules (ECMs), in one or more machines, is disclosed. The one or more ECMs are switchably connected to a testing unit (TU). The system includes at least one ECM connector, connectable to the one or more ECMs. The at least one ECM connector is one of a male connector or a female connector. Similarly, the system includes at least one TU connector connectable with the TU. Further, at least one actuator is operably connectable to at least one of the at least one ECM connector and the at least one TU connector. The actuator is configured to facilitate an electrical connection between the ECM and the testing unit in response to a relay signal generated by the testing unit.

### TECHNICAL FIELD

The present disclosure relates generally to the testing of Electronic Control Modules (ECM) in machines. More specifically, the present disclosure relates to an automatable management system for testing one or more (ECMs).

### BACKGROUND

Electronic Control Modules (ECMs) are installed in machines to perform a variety of operations. As requirements of automation have grown over the years, ECM application has become increasingly apposite, and, therefore, a larger number of machines have progressed towards a multi-ECM usage. As ECMs contribute towards performing a variety of complex tasks, tests are required to be carried out to prevent related operational failures. A multi-ECM test may involve comprehensive examination across a number of software types and software versions.

A complication factor in testing such electronic systems is the proliferation and prevalence of different ECMs affiliated with a varied set of applications within a machine. Additionally, differing electronic systems are generally accompanied by multiple data formats that, more often than not, make ECM tests rather tedious. While some ECMs remain as stand-alone units, on occasion, some ECMs may be dependent on other ECMs and logic devices as well, thereby further complicating an associated test management process.

Amongst such inadequacies, one deficiency remains in intervening manually to change ECM connections relative to a testing unit, during a test process. More particularly, ECM testing generally necessitates an increased participation from both a test team and a ground staff. This makes the test process labor intensive. Associated coordination challenges between the two groups result in repeated connection changes, which cause substantial test inaccuracies and increased consumption of time and resources. Moreover, tests that are desirous to be carried out from remote locations become vulnerable to increased failures.

U.S. Pat. No. 4,588,244 discloses a linear actuated connector that enables electrical connection between two different circuit assemblies by use of a deflecting member. Although this reference discloses an actuation process to establish an electrical connection, the inclusion of the deflecting member adds to an aggregate bulk of the system and complexity of the connection.

Accordingly, the system and method of the present disclosure solves one or more problems set forth above and/or other problems in the art.

### SUMMARY OF THE INVENTION

Various aspects of the present disclosure illustrate an automatable management system to test one or more electronic control modules (ECMs). The one or more ECMs may belong to one or more machines. The one or more ECMs are switchably connected to a testing unit (TU). The automatable management system includes at least one ECM connector, connectable to the one or more ECMs. The at least one ECM connector is one of a male connector or a female connector. As with the ECM connector, at least one TU connector is connectable with the TU. Moreover, at least one actuator is operably connectable to at least one of the at least one ECM connector and the at least one TU connector. More particularly, the at least one actuator is configured to facilitate an electrical connection between the ECM and the TU in response to a relay signal generated by the TU.

### BRIEF DESCRIPTION OF THE DRAWINGS

FIG. 1 is an exemplary machine having an electronic control module (ECM) set connected to a component set of the machine, in accordance with the concepts of the present disclosure;

FIG. 2 is a top view of an automatable management system for testing the ECM set of FIG. 1, in accordance to the concepts of the present disclosure;

FIG. 3 is a side view of the automatable management system of FIG. 2, being in a disengaged orientation, in accordance with the concepts of the present disclosure; and

FIG. 4 is a side view of the automatable management system of FIG. 2, being in an engaged orientation, in accordance with the concepts of the present disclosure.

### DETAILED DESCRIPTION

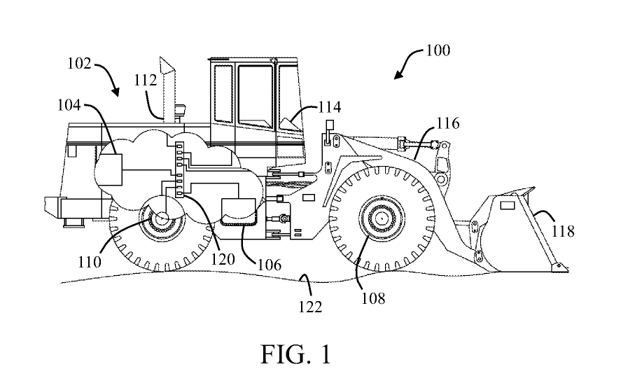

Referring to FIG. 1, there is shown a machine 100. The machine 100 may be wheel loader. However, references and an application of the present disclosure may extend to other machines, such as off-highway trucks, scrapers, motor graders, large mining truck (LMT), asphalt pavers, tracked machines, and the like. Notably, the machine 100 may embody a wheeled configuration associated with mining, agriculture, forestry, construction, and other industrial applications. An extension of an application of the present disclosure may be envisioned for machines employed in commercial establishments and personal use, as well. Moreover, machines that apply a number of electronic control modules (ECMs) may also contemplate usage of the aspects of the present disclosure.

The machine 100 includes a component set 102, which includes an engine 104, housed generally within an engine compartment of the machine 100. The component set 102 further includes a transmission unit 106, a brake unit 108, a suspension unit 110, an exhaust unit 112, a steering unit 114, a lift arm 116, and a bucket 118.

An electronic control module (ECM) set 120 is configured within the machine 100. The ECM set 120 is operably connected to the component set 102 to control a working of the component set 102. Accordingly, multiple ECMs may be configured within the ECM set 120. For example, an engine control module, a transmission control module, a powertrain control module, a central control module, a brake control module, a general electronic module, a central timing module, a body control module, an implement control module, a suspension control module, and the like. In a preferred embodiment, the ECM set 120 includes Telematic ECMs to facilitate remote testing of the ECM set 120. Although the component set 102 is disclosed here, in an embodiment, the ECM set 120 includes an extension of operable connections to other components of the machine 100, as well. Accordingly, the ECM set 120 may be envisioned to accomplish other functions in the machine 100. Therefore, the disclosed layout of the ECM set 120, relative to the component set 102, need not be seen as being limiting in any way.

The engine 104 may be an internal combustion engine. However, in an embodiment, the engine 104 may comprise other engine types. The engine 104 may be operably connected to the transmission unit 106, to transfer a rotational motion, and thereby, establish a consequent speed of operation over a working surface 122. The transmission unit 106 may transfer rotational motion towards a final drive (not shown) of the machine 100. The final drive (not shown) may operate in connection with the suspension unit 110, to facilitate ease in movement over the working surface 122. Working in conjunction within the suspension unit 110 is the brake unit 108, which may be configured to carry out operations related to controlled retardation of the machine 100. Also working in conjunction with the suspension unit 110 may be the steering unit 114, which may facilitate maneuverability of the machine 100 over the working surface 122.

At another end, the engine 104 may be fluidly connected to the exhaust unit 112 of the machine 100. Exhaust gases generated from combustion within the engine 104 may be delivered to the exhaust unit 112, to be filtered and treated before an emission into the atmosphere. Additionally, as part of the work implements, the machine 100 includes the lift arm 116 and the bucket 118. These implements may be operable by means of hydraulic actuation, although other actuation means are contemplated.

Each action and control of the component set 102 may be managed and determined by the ECM set 120. Accordingly, the ECM set 120 may generally include a number of algorithms that correspond to the working of each component within the component set 102. Therefore, a communication involved between the ECM set 120 and the component set 102 may be relatively complex. As a result, the ECM set 120 may need to undergo frequent tests for durability and operational reliability. Further, such testing may be performed to match various layouts of the ECM set 120. By implication, a multi-ECM usage would require mapping across each of the ECMs configured within the ECM set 120.

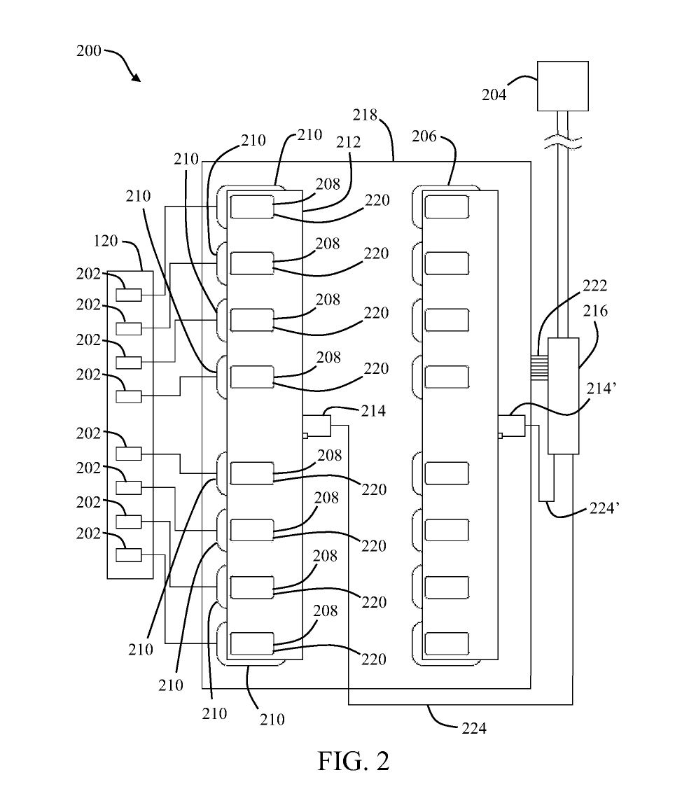

Referring to FIG. 2, an automatable management system 200 for testing the ECM set 120 is shown. More particularly, FIG. 2 illustrates a top view of the automatable management system 200. The ECM set 120 may include one or more ECMs 202, having at least one ECM 202 operably correspond to each component within the component set 102 (See FIG. 1). In the disclosed embodiment, however, the ECM set 120 includes eight ECMs 202, which may equivalently correspond to each component within the component set 102 (See FIG. 1). A different ECM number set may be contemplated.

A testing unit (TU) 204 may be switchably connected to the ECMs 202. The TU 204 may be situated at a remote location. The TU 204 may include sub-systems that manipulate and modulate connection variations in the automatable management system 200. More specifically, the TU 204 may be configured to perform multi-variant testing operations in one or more machines, on the algorithm installed within each of the ECMs 202.

In a preferred embodiment, a different version 206 of the machine 100 may be included for simultaneous or sequential tests. A multi-variant ECM test management system is thus contemplated that allows testing of ECMs applied in more than one machine. More particularly, as different machines include ECMs applicable for different purposes, the present disclosure proposes the automatable management system 200 by which operators stationed at a site of the TU 204 may desirably connect/disconnect the ECM set 120 to/from the TU 204. Those connections may be according to the requirements of a related test procedure. With reference to the present disclosure, however, the automatable management system 200 facilitates automation during a testing procedure within a single ECM set (120).

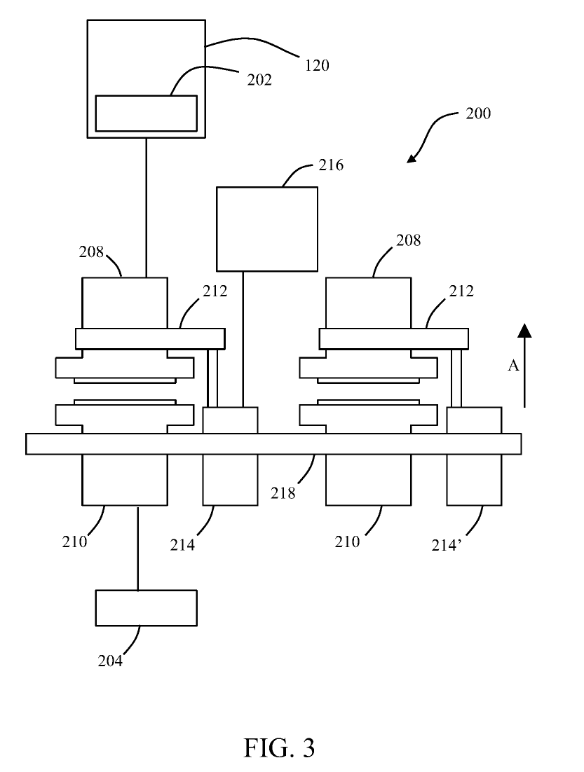

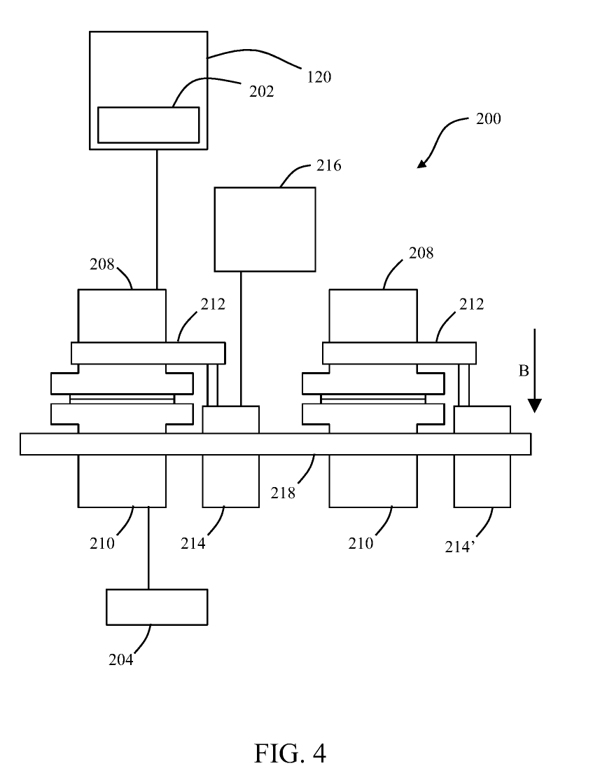

The automatable management system 200 includes at least one ECM connector 208 that is correspondingly connected to each of the ECMs 202. Also included in the automatable management system 200, is at least one TU connector 210 (also shown in FIG. 3 and FIG. 4), connected with the TU 204. Each of the at least one TU connector 210 conversely corresponds to each of the at least one ECM connector 208. At least one actuator 214 is operably connected to at least one of the ECM connectors 208 and the TU connectors 210.

The ECM connector 208 may be one of a male connector or a female connector, although other connector types of varying structures and specifications may also be used. In an embodiment, when the ECM connector 208 is a male connector, the TU connector 210 may be a female connector. Conversely, when the ECM connector 208 is a female connector, the TU connector 210 may be a male connector. When mated, both the ECM connector 208 and the TU connector 210 may be configured to transmit data across the mated connection. In an embodiment, both the ECM connector 208 and the TU connector may be 70-pin connectors, but connectors with other pin counts and also other types of connectors may be utilized.

A connector guide 212 may be connected to each of the ECM connectors 208. The connector guide 212 may facilitate simultaneous connection/disconnection of all ECM connectors 208 to/from the TU connectors 210, during testing. More particularly, the connector guide 212 may undergo physical actuation relative to the TU connectors 210 to facilitate the connection/disconnection. The connector guides 212 may include ECM slots 220 to generally hold the ECM connectors 208 therein. The connector guide 212 may be a plate, bar, or an elongated member, that may be fixedly connected to each ECM connector 208.

For a comprehensive test, all the eight ECMs within the ECM set 120 may require to be tested together. However, not all versions of the machine 100 may have the same ECM set, such as the ECM set 120. Thus, to test the same machine, some ECMs 202 may be connected/disconnected to the TU 204 independent of other ECMs 202, within the ECM set 120.

Accordingly, alternatively configured connector guides may be applied when individual or pairs of ECMs 202 need to be tested separately. For example, when a pair of ECMs 202 requires a separate dedicated inspection, at least two ECM connector guides (not shown) may be incorporated. Here, a first connector guide may be connected to the said ECM pair, while a second connector guide may be connected to the remaining ECMs. Both the first connector guide and the second connector guide may operate independently of each other. For that purpose, each connector guide 212 may include a dedicated actuator, such as the actuator 214, to vary a change in connections between the TU 204 and the ECM set 120. Further variations to that mechanism may be contemplated.

Accordingly, a testing performed to match various layouts of the ECM set 120 in the machine 100 (see FIG. 1) may include more than one connector guide 212. In such cases, a change in size and shape of the connector guides 212 may be contemplated. On occasion, only a portion of the ECM set 120 may require inspection, and accordingly, the connector guide 212 may independently accommodate connectors according to the number of ECMs 202 that require the inspection.

The actuator 214 may be any of widely applied mechanical actuators known in the art. The actuator 214 may be fixedly connected to the connector guide 212 by rivets, screws, or other known measures. More particularly, the actuator 214 may be a linear actuator configured to impart a motion to the connector guide 212 along a straight line. By implication, the connector guide 212 may translate motion from the actuator 214 to the ECM connectors 208. For example, when the actuator 214 is activated upwards, relative to the mounting plate 218, the connector guide 212 lifts and disengages the ECM connectors 208 from the TU connectors 210. Conversely, when the actuator 214 is activated downwards, relative to the mounting plate 218, the connector guide 212 descends to engage the ECM connectors 208 with the TU connectors 210. Effectively, the actuator 214 may impart a motion to the ECM connectors 208 relative to the TU connectors 210.

The actuator 214 may be an electrically activated device. However, in an embodiment, the actuator 214 may perform actuation via hydraulic or pneumatic means. Examples of the actuator 214 may include, but not limited to, a screw type or a cam-activated actuator. During an operation, the actuator 214 may be configured to linearly manipulate the movement of the connector guide 212, facilitating engagement/disengagement of the ECM connector 208 to/from the TU connector 210. By use of this mechanism, the actuator 214 is configured to switch an electrical connection between the ECMs 202 and the TU 204, in response to a relay signal generated by the TU 204.

As shown, a single actuator 214 may connect/disconnect the eight ECMs connectors 208 to the TU 204. Similarly, the actuator 214′ may independently connect/disconnect eight ECM connectors 208 to/from another machine, such as the different version 206, having different specifications. Actuations in this manner, facilitates an appropriate execution of a testing process that corresponds to a specific machine version.

The automatable management system 200 also includes a controller 216. The controller 216 is operably connected between the TU 204 and the ECM set 120. In that manner, the controller 216 establishes an operable link, referred to as a TU link 222, between the TU 204 and the ECM set 120. Accordingly, testing and inspection of the ECM set 120 may be performed via the TU link 222. Similarly, the controller 216 may also establish an operable connection between the TU 204 and the actuator 214, to switchably vary the ECM connectors 208 relative to the TU connectors 210, during testing. Actuator links 224, 224′ may respectively facilitate the connection between the controller 216 and the actuators 214, 214′. Optionally, connections between the TU 204 and the actuators 214, 214′ may be wirelessly configured.

The controller 216 may be one among the known control devices used in the art. The controller 216 may be a microprocessor-based device configured to receive relay signals from the TU 204. Subsequent to the receipt of the relay signal, the controller 216 may be configured to process the signal and convert the signal into a feedback-specific format. Such a format may be compatible for a delivery to the actuator 214. More particularly, the controller 216 may include a set of volatile memory units, such as RAM and/or ROM, including associated input and output buses. In addition, the controller 216 may be envisioned as an application-specific integrated circuit, or a known logic device, which provide controller functionality, and such devices being known to those with ordinary skill in the art. In an embodiment, the controller 216 may form a portion of the TU 204, or may be configured as a stand-alone local entity in situ. Optionally, the controller 216 may be hydraulically or pneumatically operated.

The controller 216 may include a memory unit to store information relative to the requirements of the testing procedure. For example, when different versions of the machine 100 (see FIG. 1) need to be tested, the controller 216 may be pre-fed to comprehend which among the ECM connectors 208 need to be varied. Algorithms related to such functionalities may be stored within the controller 216 and/or within the TU 204.

A mounting plate 218 may be provided to stably and stationarily accommodate the TU connectors 210, as shown. Such an accommodation is operably configured relative to the ECM connectors 208. However, options may be contemplated where the ECM connectors 208 are accommodated within the mounting plate 218 instead of the TU connectors 210. As with the connector guides 212, the mounting plate 218 may also include TU slots (not shown) for an associated accommodation of the TU connectors 210, therein.

Referring to FIG. 3, there is shown a side view of the automatable management system 200, depicted in FIG. 2. Notably, the TU connector 210 may be better viewed here. Further, the automatable management system 200 is shown to be in an unmated configuration, during an exemplary testing process. The unmated configuration relates to disengagement of the ECM connector 208 from the TU connector 210, exemplifying a disconnection between the ECM set 120 and the TU 204. The unmated configuration may complement a disengaged direction A, as shown.

Referring to FIG. 4, there is shown the automatable management system 200, depicting a view similar to the view shown in FIG. 3. More particularly, the automatable management system 200 is shown to be in a mated configuration, in an engagement direction, B, during an exemplary testing process. The mated configuration relates to an engagement of the ECM connector 208 with the TU connector 210, exemplifying a connection between the ECM set 120 and the TU 204.

### INDUSTRIAL APPLICABILITY

In operation, the Electronic Control Module (ECM) set 120 may be positioned in operable/switchable connection with the testing unit (TU) 204. Subsequently, the ECM connectors 208 may be positioned in relative proximity and in operable configuration to the TU connectors 210. In that manner, a disengagement and engagement function may be executed. As part of the first step thereafter, the TU 204 may generate and transmit a relay signal to engage the ECMs 202 with the TU 204. The controller 216 may receive the relay signal and convert the received relay signal into a format readable by the actuator 214. The controller 216 may then transmit the signal to the actuator 214, via the actuator links 224, 224′, for a connection closure. As the actuator 214 receives the signal from the controller 216, the actuator 214 may pull the connector guides 212 towards the mounting plate 218, thereby engaging the ECM connector 208 to the TU connector 210. The associated engagement direction, B may be viewed in FIG. 4. The resultant engagement between the ECM connectors 208 and the TU connectors 210 facilitates a connection between the ECM set 120 and the TU 204. This allows the operators stationed at the TU 204 to test the ECM set 120 for correctness and reliability. Upon the requirement to disengage the ECM set 120 from the TU 204, the TU 204 may generate and transmit a related relay signal to facilitate connector disengagement. Such connector disengagements may occur along the associated disengagement direction A, as shown and disclosed in FIG. 3. In a similar fashion, multi-variant ECM tests may be performed where different versions (206, see FIG. 2) of the machine 100 need to be tested.

When alterations among the ECMs 202 in the ECM set 120 are desirous, the automatable management system 200 may promulgate the usage of a multi-connector guide (212) configuration. Accordingly, operators stationed at the site of the TU 204 may raise requests through the TU 204 to connect the TU 204 only to those ECMs that actually require an inspection. A resultant state of the automatable management system 200 maintains a disengaged orientation relative to those ECMs 202 that need not be tested. Provisions of such an alternative allow operators at the TU 204 to manipulate, modify, test, and calibrate, the ECMs 202 from varied connection standpoints. When a change in position of the ECM connector 208 relative to the TU connectors 210 is desired, the operators at the TU 204 may raise subsequent signals to the controller 216 to vary the connections. In that manner, operators stationed at the site of the TU 204 may substantially freely choose between connections that need to be checked. Further, this may be accomplished without manual intervention. Accordingly, remote testing on the ECM set 120 may be performed.

By establishing a remote testing provision, an inspection of the ECMs 202 may be performed across different time zones and accommodate varying work timings. More specifically, operators stationed at the TU (204) site may test the ECMs 202, even while the ground staff at an ECM site is away. This may be advantageous as the option to alter connection changes, to check the ECM 202 for workability, responsiveness, and other desired ECM aspects, rests solely with the operator(s) associated with the TU 204. Therefore, the automatable management system 200 minimizes operational and coordination challenges.

It should be understood that the above description is intended for illustrative purposes only and is not intended to limit the scope of the present disclosure in any way. Thus, those skilled in the art will appreciate that other aspects of the disclosure may be obtained from a study of the drawings, the disclosure, and the appended claim.

What is claimed is:

1. An automatable management system for testing one or more electronic control modules (ECMs) in one or more machines, the one or more ECMs being switchably connected to a testing unit (TU), the system comprising:
at least one ECM connector, connectable to the one or more ECMs, wherein the at least one ECM connector is one of:
a male connector; or
a female connector;
at least one TU connector, connectable with the TU; and
at least one actuator operably connectable to at least one of the at least one ECM connector and the at least one TU connector,
wherein the at least one actuator is configured to facilitate an electrical connection between the one or more ECMs and the TU in response to a relay signal generated by the TU.
